(19) United States
(12) Patent Application Publication
(10) Pub. No.: US 2013/0075142 A1
(43) Pub. Date: Mar. 28, 2013

(54) ADHESIVE COMPOSITION, USE THEREOF, CONNECTION STRUCTURE FOR CIRCUIT MEMBERS, AND METHOD FOR PRODUCING SAME

(71) Applicants: Hiroyuki Izawa, Tsukuba-shi (JP); Shigeki Katogi, Hitachi-shi (JP)

(72) Inventors: Hiroyuki Izawa, Tsukuba-shi (JP); Shigeki Katogi, Hitachi-shi (JP)

(73) Assignee: HITACHI CHEMICAL CO., LTD., Tokyo (JP)

(21) Appl. No.: 13/637,182

(22) PCT Filed: Mar. 24, 2011
(86) PCT No.: PCT/JP2011/057208

§ 371 Date: Dec. 7, 2012

(30) Foreign Application Priority Data
Mar. 25, 2010 (JP) 2010-070544

(51) Int. Cl. C09J 175/06; H05K 1/09; H05K 1/03; C09J 171/08; C09J 9/02

(52) U.S. Cl. CPC C09J 175/06; C09J 171/08; C09J 9/02; H05K 1/0313; H05K 1/09
USPC 174/257; 156/305; 525/395; 525/458; 525/391; 525/455; 252/500

(57) ABSTRACT

An adhesive composition for connection between a first circuit member having a first connecting terminal on the main surface and a second circuit member having a second connecting terminal on the main surface, wherein the first circuit member and/or second circuit member are made of a base material containing a thermoplastic resin with a glass transition temperature of no higher than 200° C., the first connecting terminal and/or second connecting terminal are made of ITO and/or IZO, and the adhesive composition includes a phosphate group-containing compound, the free phosphate concentration of the cured adhesive composition being no greater than 100 ppm by mass.

### TECHNICAL FIELD

The present invention relates to an adhesive composition, to the use thereof, to a circuit member connection structure and to a method for producing the same.

### BACKGROUND ART

Semiconductor elements and liquid crystal display units have traditionally employed various types of adhesives for bonding between the members in the elements. The adhesives must exhibit not only adhesion, but also heat resistance and reliability under high-temperature, high-humidity conditions. The adherends used for bonding include printed circuit boards and organic substrates such as polyimides, as well as inorganic substrates such as SiN and SiO₂, metals such as copper and aluminum, and substrates with diverse surface conditions, such as ITO (an indium and tin complex oxide), IZO (an indium oxide and zinc oxide complex), and the like.

In recent years, semiconductor elements, liquid crystal display units and wirings are being formed on organic substrates with low heat resistance, such as polyethylene terephthalate (PET), polycarbonate (PC) or polyethylene naphthalate (PEN). Consequently, materials such as wirings that are formed on such organic substrates can be formed at low temperatures, allowing the use of amorphous-structured ITO and IZO which are easy to etch and thus have excellent pattern formability.

In the past, thermosetting resins employing epoxy resins, which have high adhesion and high reliability, have been used as adhesives for semiconductor elements and liquid crystal display units (see Patent document 1, for example). The constituent components of such resins generally include an epoxy resin, a curing agent such as a phenol resin which is reactive with the epoxy resin, and a thermal latent catalyst that promotes reaction between the epoxy resin and curing agent. The thermal latent catalyst is a substance that exhibits high reactivity upon heating without reacting at storage temperatures such as room temperature, and is an important factor determining the curing temperature and curing speed, and various compounds have been selected from the viewpoint of the room temperature storage stability and heated curing speed of the adhesive. The curing conditions employed in actual processes are for curing by heating at a temperature of 170° C. to 250° C. for 1-3 hours, to accomplish the desired bonding.

However, when a semiconductor element or liquid crystal display unit and wiring are to be formed on an organic substrate with low heat resistance, such as PET, PC or PEN, the adverse effect of the heating of curing on the organic substrate and peripheral members has been a concern. Bonding with even lower temperature curing is therefore desired.

Given this situation, increasing interest is recently being focused on radical curing adhesives, used with radical polymerizing compounds such as acrylate derivatives and methacrylate derivatives, and peroxides as radical polymerization initiators. Radical curing allows rapid curing at low temperature, due to the high reactivity of radical reactive species (see Patent document 2, for example).

Amorphous ITO and IZO, on the other hand, are commonly etched using etchant solutions composed mainly of phosphoric acid. Also, in radical curing adhesives wherein radical polymerizing compounds such as acrylate derivatives or methacrylate derivatives are used in combination with peroxide radical polymerization initiators, phosphoric acid derivatives are used to improve the adhesion with metal interfaces (see Patent document 3, for example).

### CITATION LIST

### Patent Literature

[Patent document 1] Japanese Unexamined Patent Application Publication HEI No. 1-113480
[Patent document 2] International Patent Publication No. WO98/44067
[Patent document 3] Japanese Unexamined Patent Application Publication No. 2001-49228

### SUMMARY OF INVENTION

### Technical Problem

When a phosphoric acid derivative is used, however, degradation of the phosphoric acid derivative can produce large amounts of phosphoric acid, and therefore problems such as corrosion and elution of circuits made of amorphous-structured ITO or WO tend to occur after prolonged reliability testing (high-temperature, high-humidity testing).

It is therefore an object of the present invention to provide an adhesive composition that inhibits elution of connecting terminals on connecting members that have connecting terminals made of ITO or IZO, that can exhibit excellent bonding strength and can maintain stable performance (bonding strength and connection resistance) even after prolonged reliability testing (high-temperature, high-humidity testing), as well as the use thereof, a circuit member connection structure employing the adhesive composition, and a method for producing the same.

### Solution to Problem

In order to achieve the object stated above, the invention provides an adhesive composition for connection between a first circuit member having a first connecting terminal on the main surface and a second circuit member having a second connecting terminal on the main surface, wherein the first circuit member and/or second circuit member are made of a base material containing a thermoplastic resin with a glass transition temperature of no higher than 200° C., the first connecting terminal and/or second connecting terminal are made of ITO and/or IZO, and the adhesive composition includes a phosphate group-containing compound, the free phosphate concentration of the cured adhesive composition being no greater than 100 ppm by mass.

Since the adhesive composition includes a phosphate group-containing compound and the free phosphate concentration of the cured adhesive composition is no greater than 100 ppm by mass, it is possible to inhibit elution of the ITO and IZO composing the connecting terminal, excellent bonding strength can be obtained, and it is possible to maintain stable performance (bonding strength and connection resistance) even after prolonged reliability testing (high-temperature, high-humidity testing). In addition, since the adhesive composition of the invention includes the phosphate group-containing compound, it can exhibit excellent bonding strength for circuit members having connecting terminals made of metal, and particularly circuit members having connecting terminals made of ITO or IZO. In addition, an adhesive composition having such a constitution can cure at low temperature and in a short period of time, and can be suitably used as an adhesive for circuit members that are made of base materials containing thermoplastic resins with glass transition temperatures of no higher than 200° C.

The adhesive composition contains (a) a thermoplastic resin, (b) a radical polymerizing compound and (c) a radical polymerization initiator, and preferably the (b) radical polymerizing compound includes a phosphate group-containing compound. If the adhesive composition has such a constitution, it will be able to cure at low temperature and in a short period of time, and will be able to exhibit excellent bonding strength for circuit members with connecting terminals made of metal, and especially circuit members with connecting terminals made of ITO or IZO.

The (b) radical polymerizing compound in the adhesive resin composition of the invention preferably contains one or more of both a vinyl compound with a phosphate group, as the phosphate group-containing compound, and a radical polymerizing compound other than a vinyl compound with a phosphate group. This will result in a free phosphate concentration of no greater than 100 ppm by mass in the cured adhesive composition, while allowing the adhesive composition to contain a radical polymerizing compound at a level that can adequately promote radical polymerization reaction. In addition, since the (b) radical polymerizing compound includes a vinyl compound with a phosphate group, the adhesive composition can exhibit even more excellent bonding strength not only for circuit members having connecting terminals made of metal, but also for circuit members having connecting terminals made of ITO or IZO.

The adhesive composition of the invention also preferably further contains (d) conductive particles. Including (d) conductive particles can impart satisfactory conductivity or anisotropic conductivity to the adhesive composition, thereby allowing the adhesive composition to be suitably used especially for bonding between circuit members with connecting terminals (circuit electrodes). It can also more satisfactorily reduce connection resistance between terminals that have been electrically connected through the adhesive composition.

Also, either or both the first circuit member and second circuit member are preferably made of a base material containing a thermoplastic resin with a glass transition temperature of no higher than 200° C., and have a connecting terminal made of ITO and/or IZO on the main surface.

The thermoplastic resin with a glass transition temperature of no higher than 200° C. is preferably at least one selected from the group consisting of polyethylene terephthalate, polycarbonate and polyethylene naphthalate.

The present invention further provides a circuit member connection structure comprising a first circuit member having a first connecting terminal on the main surface, a second circuit member having a second connecting terminal on the main surface and a connecting member, wherein the first circuit member and the second circuit member are disposed in such a manner that the first connecting terminal and the second connecting terminal face each other via a connecting member made of the aforementioned adhesive composition, the first connecting terminal and second connecting terminal being electrically connected, and the first circuit member and/or second circuit member are made of a base material including a thermoplastic resin with a glass transition temperature of no higher than 200° C., the first connecting terminal and/or second connecting terminal being made of ITO and/or IZO. The thermoplastic resin with a glass transition temperature of no higher than 200° C. is preferably at least one selected from the group consisting of polyethylene terephthalate, polycarbonate and polyethylene naphthalate.

Since the connection structure employs the cured product of an adhesive composition of the invention (connecting member) for connection between a pair of circuit members, not only is corrosion of the connecting terminals inhibited, but the bonding strength between circuit members can be adequately increased, and stable performance can be maintained in prolonged reliability testing (standing at 85° C./85% RH, for example). The adhesive composition of the invention which is to be used as a connecting member does not require total curing (curing to the maximum degree possible at the prescribed curing conditions), and may be in a partially cured state so long as the aforementioned properties are exhibited.

Also, since the first circuit member and/or second circuit member are circuit members made of base materials including at least one type of thermoplastic resin with a glass transition temperature of no higher than 200° C., selected from the group consisting of polyethylene terephthalate, polycarbonate and polyethylene naphthalate, wettability with the adhesive composition is increased and the bonding strength is further increased, thus allowing excellent connection reliability to be obtained.

The present invention further provides a method for producing a circuit member connection structure, which comprises a step of disposing a first circuit member having a first connecting terminal on the main surface and a second circuit member having a second connecting terminal on the main surface in such a manner that the first connecting terminal and the second connecting terminal face each other, situating the adhesive composition of the invention between the first circuit member and the second circuit member and hot pressing them to form electrical connection between the first connecting terminal and second connecting terminal, wherein the first circuit member and/or second circuit member are made of a base material including a thermoplastic resin with a glass transition temperature of no higher than 200° C., the first connecting terminal and/or second connecting terminal being made of ITO and/or IZO. The thermoplastic resin with a glass transition temperature of no higher than 200° C. is preferably at least one selected from the group consisting of polyethylene terephthalate, polycarbonate and polyethylene naphthalate.

The invention still further provides the use of the adhesive composition of the invention for connection between a first circuit member having a first connecting terminal on the main surface and a second circuit member having a second connecting terminal on the main surface, wherein the first circuit member and/or second circuit member are made of a base material including a thermoplastic resin with a glass transition temperature of no higher than 200° C., the first connecting terminal and/or second connecting terminal being made of ITO and/or IZO. The thermoplastic resin with a glass transition temperature of no higher than 200° C. is preferably at least one selected from the group consisting of polyethylene terephthalate, polycarbonate and polyethylene naphthalate.

### Advantageous Effects of Invention

According to the invention it is possible to provide an adhesive composition that inhibits elution of connecting terminals on connecting members that have connecting terminals made of ITO or IZO, and that can exhibit excellent bonding strength and can maintain stable performance (bonding strength and connection resistance) even after prolonged reliability testing (high-temperature, high-humidity testing), as well as the use thereof, a circuit member connection structure employing the adhesive composition, and a method for producing the same.

### BRIEF DESCRIPTION OF DRAWINGS

FIG. 1 is a cross-sectional view of a circuit member connection structure employing an adhesive composition that does not contain conductive particles, according to an embodiment of the invention.

FIG. 2 is a cross-sectional view of a first circuit member, a second circuit member and an adhesive composition (not containing conductive particles), according to an embodiment of the invention.

FIG. 3 is a cross-sectional view of a circuit member connection structure employing an adhesive composition that contains conductive particles, according to an embodiment of the invention.

FIG. 4 is a cross-sectional view of a first circuit member, a second circuit member and an adhesive composition (containing conductive particles), according to an embodiment of the invention.

### DESCRIPTION OF EMBODIMENTS

Preferred embodiments of the invention will now be explained in detail, with reference to the accompanying drawings as necessary. Identical or corresponding parts in the drawings will be referred to by like reference numerals and will be explained only once. For the purpose of the invention, “(meth)acrylic acid” refers to acrylic acid or the corresponding methacrylic acid, “(meth)acrylate” refers to acrylate or its corresponding methacrylate, and “(meth)acryloyl group” refers to an acryloyl or methacryloyl group.

Also, for the purpose of the invention, “corrosion” refers to elution and loss of at least part of a circuit (connecting terminal) by chemical or electrochemical reaction.

In addition, for the purpose of the invention, the weight-average molecular weight and number-average molecular weight are the values measured using a calibration curve based on standard polystyrene in gel permeation chromatography (GPC), under the conditions shown in Table 1.

TABLE 1

| Apparatus | GPC-8020, Tosoh | |
|---|---|---|
| Detector | RI-8020 Tosoh | |
| Column | Gelpack GL-A-160-S+Gl-A150- | |
| | SG20000Hhr, Hitachi Chemical | |
| Sample concentration | 120 | mg/3 ml |
| Solvent | Tetrahydrofuran | |
| Injection volume | 60 | μl |
| Pressure | 30 | kgf/cm² |
| Flow rate | 1.00 | ml/min |

The adhesive composition of this embodiment is an adhesive composition for connection between a first circuit member having a first connecting terminal on the main surface and a second circuit member having a second connecting terminal on the main surface, wherein the first circuit member and/or second circuit member are made of a base material containing a thermoplastic resin with a glass transition temperature of no higher than 200° C., the first connecting terminal and/or second connecting terminal are made of ITO and/or IZO, and the adhesive composition includes a phosphate group-containing compound, the free phosphate concentration of the cured adhesive composition being no greater than 100 ppm by mass.

According to the invention, the “free phosphate concentration of the cured adhesive composition” is the concentration of compounds with phosphate functional groups (phosphate group-containing compounds) freed from the cured adhesive composition obtained after drying at 180° C. for 1 hour with hot air.

Also according to the invention, the “free phosphate concentration” refers to the value measured for an extract obtained by adding a sample (cured adhesive composition) and ultrapure water to an autoclave vessel to a sample content of 1 mass % and conducting treatment under high-temperature, high-pressure conditions of 121° C., hours, 0.2 MPa, and then subjecting the extract to ion chromatography under the conditions listed in Table 2, and using a calibration curve obtained for an Anion Mixed Standard Solution IV (Kanto Kagaku Co., Ltd.).

TABLE 2

| Apparatus | IC-20 Ion Chromatograph, Dionex | |
|---|---|---|
| Detector | Conductivity detector | |
| Column | Ion Pac AS9-HC, Dionex | |
| Column temperature | 25° C. | |
| Suppressor | ASRS-ULTRAII 100 mA, Dionex | |
| Sample concentration | 0.01 | mg/1 ml |
| Solvent | 9 | mM sodium carbonate solution |
| Injection volume | 1 | μl |
| Flow rate | 1.00 | ml/min |

The concentration of free phosphate group-containing compounds in the cured product must be no greater than 100 ppm by mass, and is preferably no greater than 80 ppm by mass and more preferably no greater than 60 ppm by mass. If the free phosphate concentration in the cured adhesive composition is no greater than 100 ppm by mass, it will be possible to inhibit elution of connecting terminals made of ITO, IZO and metals. The lower limit for the concentration of free phosphate group-containing compounds in the cured product is preferably 0 ppm by mass, but from the viewpoint of material availability it is preferably 1 ppm by mass and especially 20 ppm by mass.

Each of these components will now be explained. The (a) thermoplastic resin to be used for the invention is a resin (polymer) having properties that allow it to be freely deformed by external force when in a highly viscous fluid state produced by heating, and to become hard while retaining the form after cooling and removal of the external force, and that allows this process to be repeated. This also includes resins (polymers) with reactive functional groups that exhibit such properties. The Tg of the (a) thermoplastic resin is preferably 0° C. to 190° C. and more preferably 20° C. to 170° C.

As such thermoplastic resins there may be used polyimide resins, polyamide resins, phenoxy resins, (meth)acrylic resins, urethane resins, polyester-urethane resins, polyvinyl butyral resins, and the like. Any of these may be used alone or in mixtures of two or more. These thermoplastic resins may also contain siloxane bonds or fluorine substituents. These may be suitably used in a state which allows complete compatibilization between resins, or which produces microphase separation and turbidity.

When the adhesive composition is to be used as a film, a larger molecular weight of the thermoplastic resin will facilitate film formability, and will allow a wide range to be set for the melt viscosity which affects the flow property of the film-like adhesive composition. The weight-average molecular weight of the (a) thermoplastic resin is preferably 5,000-150,000 and most preferably 10,000-80,000. A value of at least 5,000 will tend to result in satisfactory film formability, and a value of no greater than 150,000 will tend to result in satisfactory compatibility with other components.

The content of the (a) thermoplastic resin in the adhesive composition is preferably 5-80 mass % and more preferably 15-70 mass % based on the total mass of the adhesive composition. A content of at least 5 mass % will tend to result in satisfactory film formability, especially when the adhesive composition is used in the form of a film, while a content of no greater than 80 mass % will tend to result in a satisfactory flow property for the adhesive composition.

The (b) radical polymerizing compound is a compound that produces radical polymerization under the action of a radical polymerization initiator, and it may be a compound that generates radicals upon application of activating energy such as light or heat.

The adhesive composition contains at least a phosphate group-containing compound, and the phosphate group-containing compound is preferably one that functions as the (b) radical polymerizing compound. A phosphate group-containing compound to be used as the (b) radical polymerizing compound is preferably a vinyl compound with a phosphate group (phosphate group-containing vinyl compound). By using a phosphate group-containing vinyl compound, the adhesive composition can improve adhesion with circuit members having connecting terminals made of metal, and circuit members having connecting terminals made of ITO or IZO.

The phosphate group-containing vinyl compound is not particularly restricted so long as it is a compound with a phosphate group and a vinyl group, but more preferred are phosphoric acid (meth)acrylate compounds having in the molecule at least one (meth)acryloyl group, which has excellent radical polymerizability, as the vinyl group. Such compounds include compounds represented by the following formulas (A) to (C). When degradation of the phosphate group-containing vinyl compound produces phosphate group-containing compounds without vinyl groups, these may be removed or reduced for suitability as an adhesive composition. The phosphate group-containing vinyl compound is more preferably a phosphate group-containing vinyl compound with 2 or more vinyl groups, even more preferably a phosphate group-containing vinyl compound with 2 vinyl groups, and especially preferably a phosphate group-containing vinyl compound with 2 vinyl groups that is represented by the following formula (A) or (B). By using a compound represented by the following formula (A) or (B) as the phosphate group-containing vinyl compound, it is possible to obtain satisfactory bonding strength without lowering the properties of the cured adhesive composition.

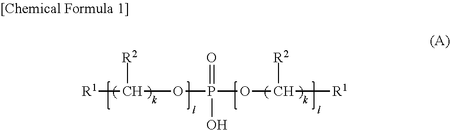

[In formula (A), R¹ represents a (meth)acryloyloxy group, R² represents hydrogen or a methyl group, and k and l each independently represent an integer of 1 to 8. Also, each R¹, R², k and l in the formula may be either the same or different.]

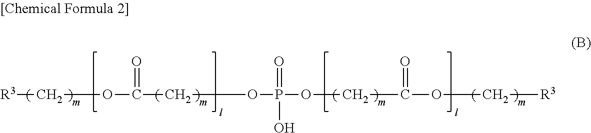

[In formula (B), R³ represents a (meth)acryloyloxy group, and m and n each independently represent an integer of 1 to 8. Also, each R³, m and n in the formula may be either the same or different.]

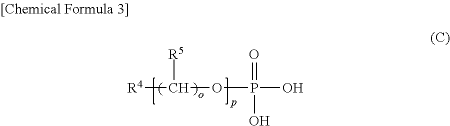

[In formula (C), R⁴ represents a (meth)acryloyloxy group, R⁵ represents hydrogen or a methyl group, and o and p each independently represent an integer of 1 to 8. Also, each R⁴, R⁵, o and p in the formula may be either the same or different.]

Phosphate group-containing vinyl compounds include, more specifically, acid phosphooxyethyl methacrylate, acid phosphooxyethyl acrylate, acid phosphooxypropyl methacrylate, acid phosphooxy polyoxyethyleneglycol monomethacrylate, acid phosphooxy polyoxypropyleneglycol monomethacrylate, 2,2′-di(meth)acryloyloxydiethyl phosphate, EO-modified phosphoric acid dimethacrylate, phosphoric acid-modified epoxy acrylate and vinyl phosphate. Particularly satisfactory bonding strength can be obtained by using 2,2′-di(meta)acryloyloxydiethyl phosphate or EO-modified phosphoric acid dimethacrylate.

The content of phosphate group-containing compounds such as phosphate group-containing vinyl compounds in the adhesive resin composition is preferably 0.2-100 parts by mass, more preferably 1-50 parts by mass and most preferably 1-5 parts by mass with respect to the 100 parts by mass of the (a) thermoplastic resin, independently of the content of radical polymerizing compounds other than phosphate group-containing compounds. If the content of phosphate group-containing compounds is at least 0.2 part by mass it will tend to be easier to obtain high bonding strength, and if it is no greater than 100 parts by mass, the physical properties of the adhesive composition after curing will not be easily reduced and it will tend to be easier to ensure reliability.

As the (b) radical polymerizing compound in the adhesive composition it is preferred to use a phosphate group-containing compound in combination with a radical polymerizing compound other than the phosphate group-containing compound. In particular, the adhesive composition preferably contains one or more of both the phosphate group-containing vinyl compound, and a radical polymerizing compound other than the phosphate group-containing vinyl compound.

Examples of radical polymerizing compounds other than phosphate group-containing compounds, that are suitable for use, include compounds with functional groups that polymerize by active radicals, such as vinyl, (meth)acryloyl, allyl and maleimide. Specifically, such radical polymerizing compounds include oligomers such as epoxy(meth)acrylate oligomer, urethane(meth)acrylate oligomer, polyether(meth)acrylate oligomer and polyester(meth)acrylate oligomer, trimethylolpropane tri(meth)acrylate, polyethyleneglycol di(meth)acrylate, polyalkyleneglycol di(meth)acrylate, dicyclopentenyl(meth)acrylate, dicyclopentenyloxyethyl(meth)acrylate, neopentyl glycol di(meth)acrylate, dipentaerythritol hexa(meth)acrylate, isocyanuric acid-modified bifunctional(meth)acrylate, isocyanuric acid-modified trifunctional(meth)acrylate, bisphenoxyethanolfluorene acrylate, epoxy(meth)acrylates with (meth)acrylic acid added to the glycidyl group of a bisphenolfluorenediglycidyl ether, bisphenoxyethanolfluorene acrylate, epoxy(meth)acrylates with (meth)acrylic acid added to the glycidyl group of a bisphenolfluorenediglycidyl ether, compounds having a (meth)acryloyloxy group introduced into a compound having ethylene glycol or propylene glycol added to the glycidyl group of a bisphenolfluorenediglycidyl ether, and compounds represented by the following formulas (D) and (E).

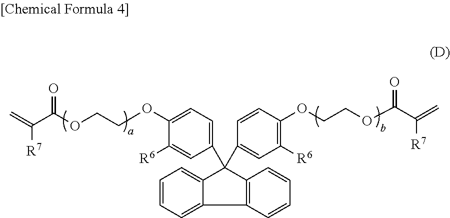

[In formula (D), R⁶ and R⁷ each independently represent hydrogen or a methyl group, and a and b each independently represent an integer of 1 to 8.]

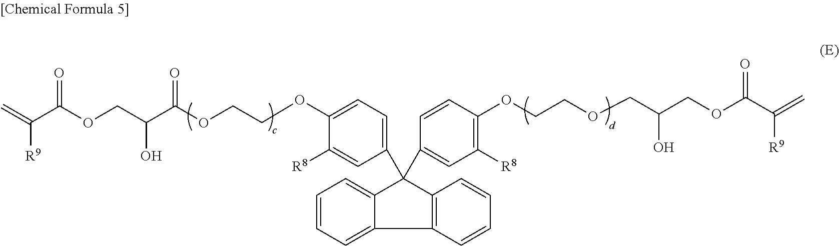

[In formula (E), R⁸ and R⁹ each independently represent hydrogen or a methyl group, and c and d each independently represent an integer of 0 to 8.]

The radical polymerizing compounds other than phosphate group-containing compounds may be used without any particular restrictions, even if they exhibit a solid state without a flow property, such as a waxy, cerate, crystalline, glassy or powder form, when allowed to stand alone at 30° C. Such radical polymerizing compounds include, specifically, N,N′-methylenebisacrylamide, diacetoneacrylamide, N-methylolacrylamide, N-phenylmethacrylamide, 2-acrylamide-2-methylpropanesulfonic acid, tris(2-acryloyloxyethyl)isocyanurate, N-phenylmaleimide, N-(o-methylphenyl)maleimide, N-(m-methylphenyl)maleimide, N-(p-methylphenyl)-maleimide, N-(o-methoxyphenyl)maleimide, N-(m-methoxyphenyl)maleimide, N-(p-methoxyphenyl)-maleimide, N-methylmaleimide, N-ethylmaleimide, N-octylmaleimide, 4,4′-diphenylmethanebismaleimide, m-phenylenebismaleimide, 3,3′-dimethyl-5,5′-diethyl-4,4′-diphenylmethanebismaleimide, 4-methyl-1,3-phenylenebismaleimide, N-methacryloxymaleimide, N-acryloxymaleimide, 1,6-bismaleimide-(2,2,4-trimethyl)hexane, N-methacryloyloxysuccinic acid imide, N-acryloyloxysuccinic acid imide, 2-naphthyl methacrylate, 2-naphthyl acrylate, pentaerythritol tetraacrylate, divinylethylene urea, divinylpropylene urea, 2-polystyrylethyl methacrylate, N-phenyl-N-(3-methacryloyloxy-2-hydroxypropyl)-p-phenylenediamine, N-phenyl-N-(3-acryloyloxy-2-hydroxypropyl)-p-phenylenediamine, tetramethylpiperidyl methacrylate, tetramethylpiperidyl acrylate, pentamethylpiperidyl methacrylate, pentamethylpiperidyl acrylate, octadecyl acrylate, N-t-butylacrylamide, diacetoneacrylamide, N-(hydroxymethyl)acrylamide, and compounds represented by the following formulas (F) to (O).

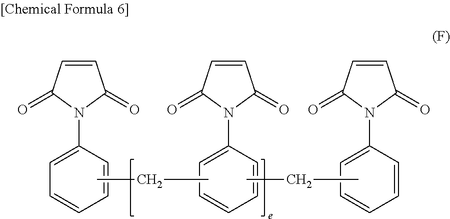

[In formula (F), e represents an integer of 1 to 10.]

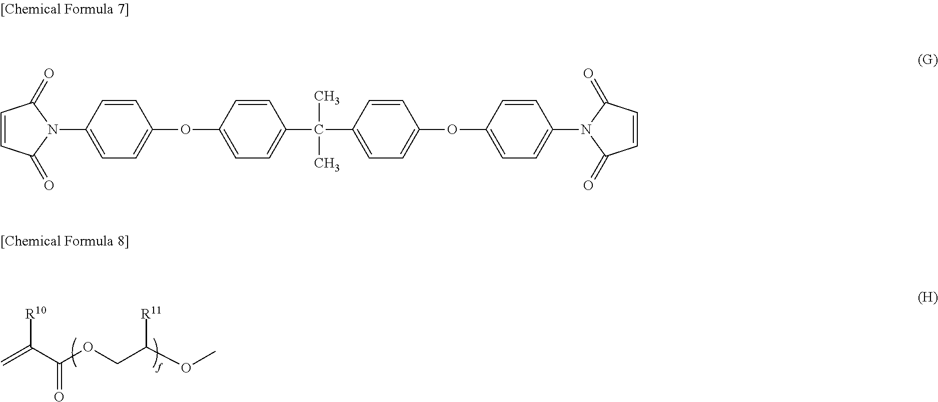

[In formula (H), R¹⁰ and R¹¹ each independently represent hydrogen or a methyl group, and f represents an integer of 15 to 30.]

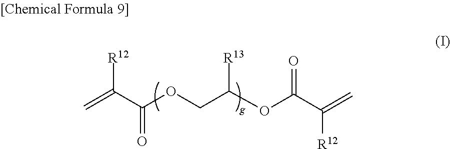

[In formula (I), R¹² and R¹³ each independently represent hydrogen or a methyl group, and g represents an integer of 15 to 30.]

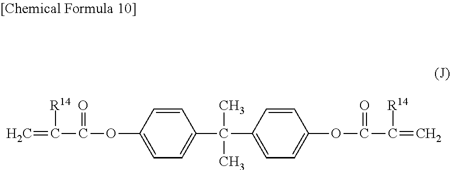

[In formula (J), R¹⁴ represents hydrogen or a methyl group.]

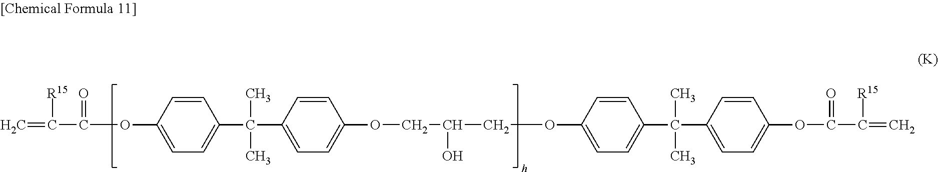

[In formula (K), R¹⁵ represents hydrogen or a methyl group, and i represents an integer of 1 to 10.]

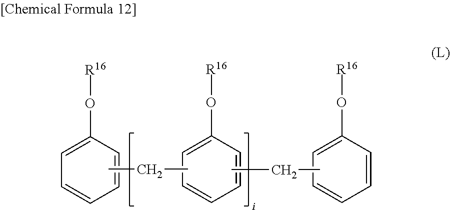

[In formula (L), R¹⁶ represents hydrogen or an organic group represented by the following formula (i) or (ii), and i represents an integer of 1 to 10.]

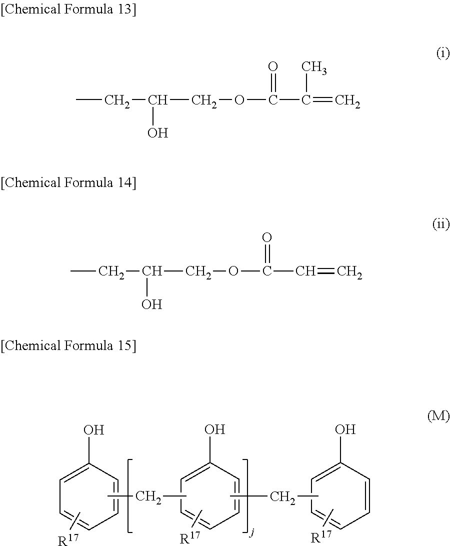

[In formula (M), R¹⁷ represents hydrogen or an organic group represented by the following formula (iii) or (iv), and j represents an integer of 1 to 10.]

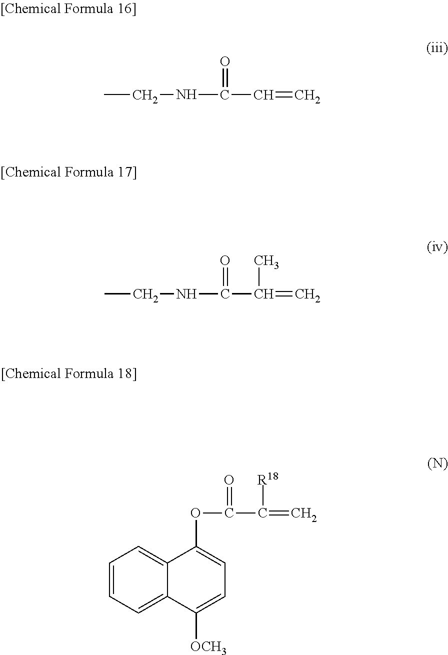

[In formula (N), R¹⁸ represents hydrogen or a methyl group.]

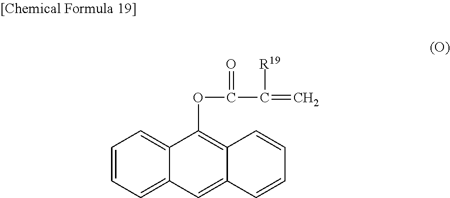

[In formula (O), R¹⁹ represents hydrogen or a methyl group.]

An N-vinyl-based compound selected from the group consisting of N-vinyl compounds and N,N-dialkylvinyl compounds, which are compounds categorized as (b) radical polymerizing compounds, may also be used in combination with other (b) radical polymerizing compounds. Combination of an N-vinyl-based compound can increase the crosslinking rate of the adhesive composition.

Specific N-vinyl-based compounds include N-vinylimidazole, N-vinylpyridine, N-vinylpyrrolidone, N-vinylformamide, N-vinylcaprolactam, 4,4′-vinylidenebis(N,N-dimethylaniline), N-vinylacetamide, N,N-dimethylacrylamide and N,N-diethylacrylamide.

The content of radical polymerizing compounds other than compounds included among the aforementioned phosphate group-containing compounds, in the adhesive composition, is preferably 50-250 parts by mass and more preferably 60-150 parts by mass with respect to 100 parts by mass of the (a) thermoplastic resin. A content of at least 50 parts by mass will tend to more easily result in sufficient heat resistance after curing. Also, a content of no greater than 250 parts by mass will tend to more easily result in satisfactory film formability when the adhesive composition is to be used as a film.

The (c) radical polymerization initiator to be used in the adhesive composition may be a compound that generates radicals upon application of external energy, such as a conventionally known organic peroxide or azo compound. From the viewpoint of stability, reactivity and compatibility, the (c) radical polymerization initiator is preferably an organic peroxide with a one-minute half-life temperature of 90° C. to 175° C. and a molecular weight of 180 to 1,000. If the one-minute half-life temperature is within this range, the storage stability will be excellent, the radical-polymerizing property will be sufficiently high, and curing will be possible within a short period of time.

Specific examples for the (c) radical polymerization initiator include organic peroxides such as 1,1,3,3-tetramethylbutyl peroxy-neodecanoate, di(4-t-butylcyclohexyl)peroxy dicarbonate, di(2-ethylhexyl)peroxy dicarbonate, cumyl peroxy-neodecanoate, 1,1,3,3-tetramethylbutyl peroxy-neodecanoate, dilauroyl peroxide, 1-cyclohexyl-1-methylethylperoxy-neodecanoate, t-hexyl peroxy-neodecanoate, t-butyl peroxy-neodecanoate, t-butyl peroxypivalate, 1,1,3,3-tetramethylbutylperoxy-2-ethyl hexanoate, 2,5-dimethyl-2,5-di(2-ethylhexanoylperoxy)hexane, t-hexylperoxy-2-ethyl hexanoate, t-butylperoxy-2-ethyl hexanoate, t-butyl peroxy-neoheptanoate, t-amylperoxy-2-ethyl hexanoate, di-t-butyl peroxy-hexahydroterephthalate, t-amylperoxy-3,5,5-trimethyl hexanoate, 3-hydroxy-1,1-dimethylbutyl peroxy-neodecanoate, 1,1,3,3-tetramethylbutylperoxy-2-ethyl hexanoate, t-amyl peroxy-neodecanoate, t-amylperoxy-2-ethyl hexanoate, di(3-methylbenzoyl)peroxide, dibenzoyl peroxide, di(4-methylbenzoyl)peroxide, t-hexylperoxyisopropyl monocarbonate, t-butylperoxymaleic acid, t-butylperoxy-3,5,5-trimethyl hexanoate, t-butyl peroxylaurate, 2,5-dimethyl-2,5-di(3-methylbenzoylperoxy)hexane, t-butylperoxy-2-ethylhexyl monocarbonate, t-hexylperoxybenzoate, 2,5-dimethyl-2,5-di(benzoylperoxy)hexane, t-butylperoxybenzoate, dibutylperoxytrimethyl adipate, t-amyl peroxy-normal-octoate, t-amyl peroxyisononanoate and t-amylperoxybenzoate; and azo compounds such as 2,2′-azobis-2,4-dimethylvaleronitrile, 1,1′-azobis(1-acetoxy-1-phenylethane), 2,2′-azobisisobutyronitrile, 2,2′-azobis(2-methylbutyronitrile), dimethyl-2,2′-azobisisobutyronitrile, 4,4′-azobis(4-cyanovaleric acid) and 1,1′-azobis(1-cyclohexanecarbonitrile). These compounds may be used alone, or two or more different compounds may be used in combination.

As the (c) radical polymerization initiator there may also be used a compound that generates radicals by photoirradiation at 150-750 nm. More preferred examples of such compounds are the α-acetoaminophenone derivatives and phosphine oxide derivatives described in Photoinitiation, Photopolymerization, and Photocuring, J.-P. Fouassier, Hanser Publishers (1995), p 17-p35, because of their high sensitivity to photoirradiation. These compounds may be used alone, or they may be used in combination with the aforementioned organic peroxides or azo compounds.

The content of the (c) radical polymerization initiator in the adhesive composition is preferably 0.1-500 parts by mass and more preferably 1-300 parts by mass with respect to 100 parts by mass of the (a) thermoplastic resin. If the amount of the (c) radical polymerization initiator added is at least 0.1 part by mass, it will tend to be easy to adequately cure the adhesive composition, and if it is no greater than 500 parts by mass, satisfactory storage stability will tend to be obtained.

The (d) conductive particles to be used for the adhesive composition may be particles that are conductive throughout or on the surface, and when the composition is to be used for connection of a circuit member with a connecting terminal, particles with smaller mean particle sizes than the distance between the connecting terminals are used.

Such (d) conductive particles include metallic particles such as Au, Ag, Ni, Cu or solder, and carbon particles. Alternatively, non-conductive glass, ceramic, plastic or the like may be used as a core, covered with the aforementioned metals, metallic particles or carbon. Preferably, the (d) conductive particles have a plastic core and are covered with the aforementioned metal or metallic particles or carbon, or they are heat-fusible metallic particles, since they will be deformable by heated pressure and therefore the contact area with electrodes during connection will be increased, thereby improving the reliability.

Fine particles in which the surfaces of the (d) conductive particles are further covered with a polymer resin or the like, will prevent shorting by a contact that occurs between particles when the conductive particle content is increased, and will thus improve the insulating property between electrode circuits. They may be used alone or in admixture with the (d) conductive particles, as appropriate.

The mean particle size of the (d) conductive particles is preferably 1-18 μm from the viewpoint of dispersibility and conductivity. If the adhesive composition comprises such (d) conductive particles, it can be suitably used as an anisotropic conductive adhesive composition.

The content of the (d) conductive particles in the adhesive composition is not particularly restricted, but it is preferably 0.1-30 vol % and more preferably 0.1-10 vol % based on the total solid volume of the adhesive composition. If the value is at least 0.1 vol % the conductivity will tend to be increased, and if it is no greater than 30 vol % there will tend to be greater resistance to circuit shorting. The vol % is determined based on the volume of each component before curing at 23° C., the volume of each component being converted from weight to volume utilizing the specific gravity. Also, the component may be loaded into a vessel such as a graduated cylinder containing an appropriate solvent (water, alcohol or the like) that thoroughly wets the component without dissolving or swelling it, and the volume calculated based on the increase in volume.

A stabilizer may also be added to the adhesive composition in order to control the curing speed and impart storage stability. Any known stabilizers may be used without any particular restrictions, although quinone derivatives such as benzoquinone and hydroquinone, phenol derivatives such as 4-methoxyphenol and 4-t-butylcatechol, aminoxyl derivatives such as 2,2,6,6-tetramethylpiperidine-1-oxyl and 4-hydroxy-2,2,6,6-tetramethylpiperidine-1-oxyl, and hindered amine derivatives such as tetramethylpiperidyl methacrylate are preferred.

The amount of stabilizer added is preferably 0.01-30 parts by mass and more preferably 0.05-10 parts by mass with respect to 100 parts by mass of the adhesive composition, excluding the stabilizer. If the amount added is at least 0.01 part by mass it will tend to be easier to control the curing speed and impart storage stability, while if it is no greater than 30 parts by mass, there will tend to be less adverse effect on the compatibility with other components.

The adhesive composition may also contain added coupling agents such as alkoxysilane derivatives or silazane derivatives, or adhesion aids such as adhesion enhancers and leveling agents, as appropriate. As coupling agents there are preferred, specifically, compounds represented by the following formula (P), and an adhesion aid may be used alone or as a mixture of 2 or more different compounds.

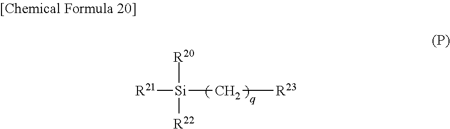

[In formula (P), R²⁰, R²¹ and R²² each independently represent hydrogen, C1-5 alkyl, C1-5 alkoxy, C1-5 alkoxycarbonyl or aryl, R²³ represents (meth)acryloyl, vinyl, isocyanato, imidazole, mercapto, amino, methylamino, dimethylamino, benzylamino, phenyl amino, cyclohexylamino, morpholino, piperazino, ureido or glycidyl, and q represents an integer of 1-10.]

A rubber component may also be used together with the adhesive composition for improved stress relaxation and adhesion. A rubber component is either a component that exhibits rubber elasticity by itself (according to JIS K6200, for example), or a component that exhibits rubber elasticity upon reaction. The rubber component may be either solid or liquid at room temperature (25° C.), but it is preferably liquid from the viewpoint of an improved flow property. The rubber component is preferably a compound with a polybutadiene backbone. The rubber component may also have a cyano, carboxyl, hydroxyl, (meth)acryloyl or morpholine group. From the viewpoint of increasing adhesion, there are preferred rubber components containing highly polar groups such as cyano or carboxyl groups on a side chain or at the ends. When thermoplasticity is exhibited, even with a polybutadiene backbone, the component is classified as component (a), and when it exhibits a radical-polymerizing property it is classified as component (b).

Specific rubber components include polyisoprene, polybutadiene, carboxyl-terminated polybutadiene, hydroxyl-terminated polybutadiene, 1,2-polybutadiene, carboxyl-terminated 1,2-polybutadiene, hydroxyl-terminated 1,2-polybutadiene, acrylic rubber, styrene-butadiene rubber, hydroxyl-terminated styrene-butadiene rubber, acrylonitrile-butadiene rubber, acrylonitrile-butadiene rubber having a carboxyl, hydroxyl, (meth)acryloyl or morpholine group on the polymer ends, carboxylated nitrile rubber, hydroxyl-terminated poly(oxypropylene), alkoxysilyl group-terminated poly(oxypropylene), poly(oxytetramethylene)glycol and polyolefin glycols.

Specific rubber components that have highly polar groups and are liquid at room temperature include liquid acrylonitrile-butadiene rubber, liquid acrylonitrile-butadiene rubber containing carboxyl, hydroxyl, (meth)acryloyl or morpholine groups at the polymer ends, and liquid carboxylated nitrile rubber. The polar acrylonitrile content of these rubber components that are liquid at room temperature is preferably 10-60 mass %. These rubber components may be used alone, or two or more different compounds may be used in combination.

The adhesive composition may also employ organic fine particles in combination, for improved stress relaxation and adhesion. The mean particle size of the organic fine particles is preferably 0.05 to 1.0 μm. When the organic fine particles are composed of the aforementioned rubber component, they are considered to be the rubber component instead of organic fine particles, and when the organic fine particles are composed of the (a) thermoplastic resin they are considered to be the (a) thermoplastic resin instead of organic fine particles.

Specific organic fine particles include organic fine particles that are composed of polyisoprene, polybutadiene, carboxyl-terminated polybutadiene, hydroxyl-terminated polybutadiene, 1,2-polybutadiene, carboxyl-terminated 1,2-polybutadiene, acrylic rubber, styrene-butadiene rubber, acrylonitrile-butadiene rubber, acrylonitrile-butadiene rubber having carboxyl, hydroxyl, (meth)acryloyl or morpholine groups on the polymer ends, carboxylated nitrile rubber, hydroxyl-terminated poly(oxypropylene), alkoxysilyl group-terminated poly(oxypropylene), poly(oxytetramethylene)glycol, polyolefin glycol alkyl (meth)acrylate-butadiene-styrene copolymer, alkyl-silicone (meth)acrylate copolymer or silicone-(meth)acrylic copolymer, or complexes. These organic fine particles may be used alone, or two or more different compounds may be used in combination.

The adhesive composition may be used in paste form if it is a liquid at ordinary temperature. When it is a solid at room temperature, it may be heated, or formed into a paste using a solvent. The solvent used is preferably one that does not react with the adhesive composition or additives and that exhibits sufficient solubility, but it is preferably one with a boiling point of 50° C. to 150° C. at ordinary pressure. If the boiling point is 50° C. or higher, there will tend to be lower risk of volatilization when allowed to stand at room temperature, and use in open systems will tend to be facilitated. If the boiling point is no higher than 150° C., it will be easy to evaporate off the solvent and there will tend to be less adverse effects on the reliability after adhesion.

The adhesive composition may also be used after its shaping into a film. A solution obtained by adding a solvent or the like to the adhesive composition as necessary may be coated onto a releasable base material such as a fluorine resin film, polyethylene terephthalate film or release sheet, or a base material such as a nonwoven fabric may be impregnated with the solution and placed on a releasable base material, and the solvent subsequently removed for use as a film. The use of the adhesive composition in the form of a film is even more convenient from the standpoint of manageability.

The adhesive composition may also be bonded with a combination of heating and pressurization. The heating temperature is preferably a temperature of 100° C. to 200° C. The pressure is preferably in a range that does not damage the adherend, and usually 0.1 to 10 MPa is preferred. The pressing and heating are preferably carried out for a period in a range of 0.5 to 120 seconds, and the bonding may be by heating at 140° C. to 190° C., 3 MPa for 10 seconds.

The adhesive composition may be used as an adhesive for adherends with different thermal expansion coefficients. Specifically, it may be used as a circuit connecting material such as an anisotropic conductive adhesive, silver paste, silver film or the like, or as a semiconductor element adhesive material such as CSP elastomer, CSP underfill material, LOC tape or the like.

The adhesive composition of the invention may be used as an adhesive composition for connection between a first circuit member having a first connecting terminal on the main surface and a second circuit member having a second connecting terminal on the main surface. Either or both the first circuit member and second circuit member are made of a base material containing a thermoplastic resin with a glass transition temperature of no higher than 200° C., and the first connecting terminal and/or second connecting terminal are made of ITO and/or IZO. There are no particular restrictions on the thermoplastic resin with a glass transition temperature of no higher than 200° C., and it may be, for example, polyethylene terephthalate, polycarbonate or polyethylene naphthalate.

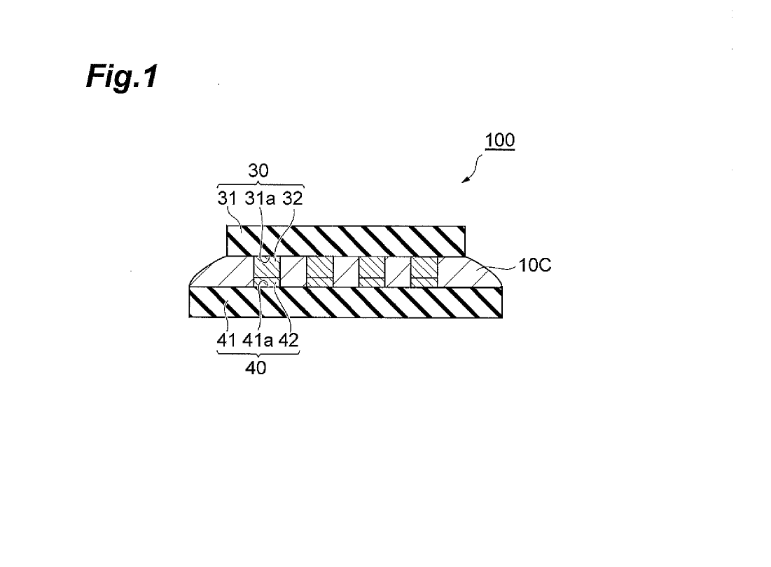

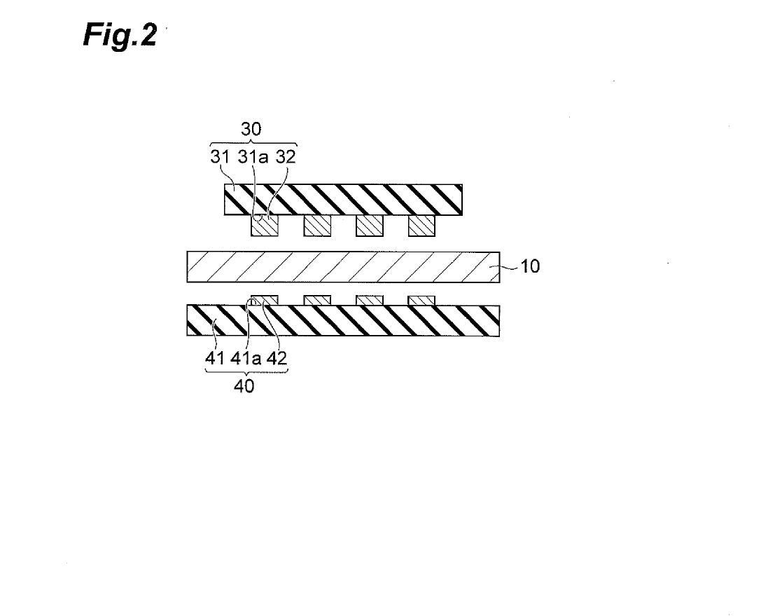

The circuit member connection structure employing an adhesive composition of the invention will now be described. FIG. 1 is a schematic cross-sectional view of an embodiment of a circuit member connection structure employing an adhesive composition of the invention that does not contain (d) conductive particles. FIG. 2 is a schematic cross-sectional view of a first circuit member, a second circuit member and an adhesive composition (not containing conductive particles), before forming the circuit member connection structure shown in FIG. 1.

The circuit member connection structure 100 shown in FIG. 1 comprises a first circuit member 30 having a first connecting terminal 32 on the main surface 31a of a first circuit board 31, a second circuit member 40 having a second connecting terminal 42 on the main surface 41a of a second circuit board 41, and a connecting member 10C that connects the main surface 31a of the first circuit board 31 and the main surface 41a of the second circuit board 41, in such a manner that the first connecting terminal 32 and second connecting terminal 42 are facing each other. The first connecting terminal 32 and second connecting terminal 42 are electrically connected by being in mutual contact. The connecting member 10C is made of a cured adhesive composition 10 of the invention.

The circuit member connection structure 100 shown in FIG. 1 may be produced in the following manner, for example.

For example, as shown in FIG. 2, there are prepared the first circuit member 30, the second circuit member 40 and the adhesive composition 10 that has been formed into a film. Next, the adhesive composition 10 is placed on the main surface 42a of the second circuit member 40 on which the second connecting terminal 42 has been formed, and the first circuit member 30 is placed over the adhesive composition 10, with the first connecting terminal 32 facing the second connecting terminal 42. Next, the stack is cured while heating the adhesive composition 10 through the first circuit member 30 and second circuit member 40, and while simultaneously pressing in the direction normal to the main surfaces 31a, 41a, thus forming a connecting member 10C between the first and second circuit members 30, 40 to obtain the circuit member connection structure 100 shown in FIG. 1.

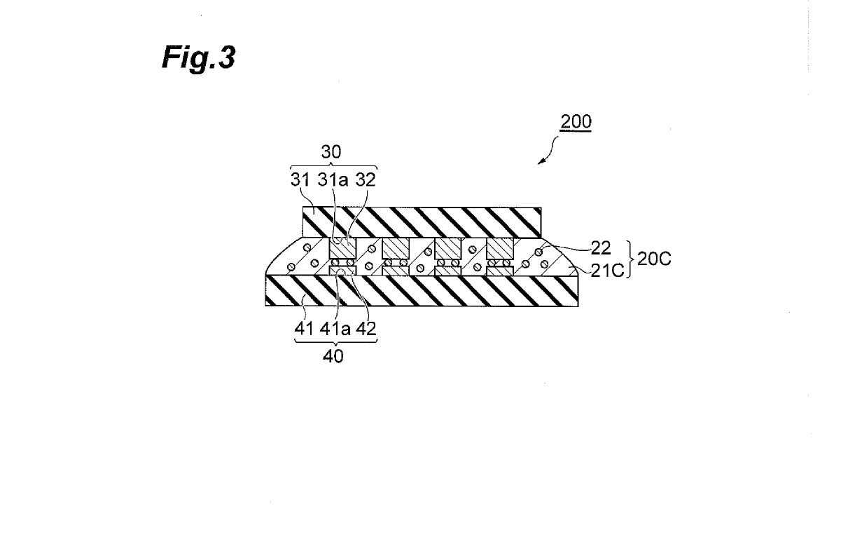

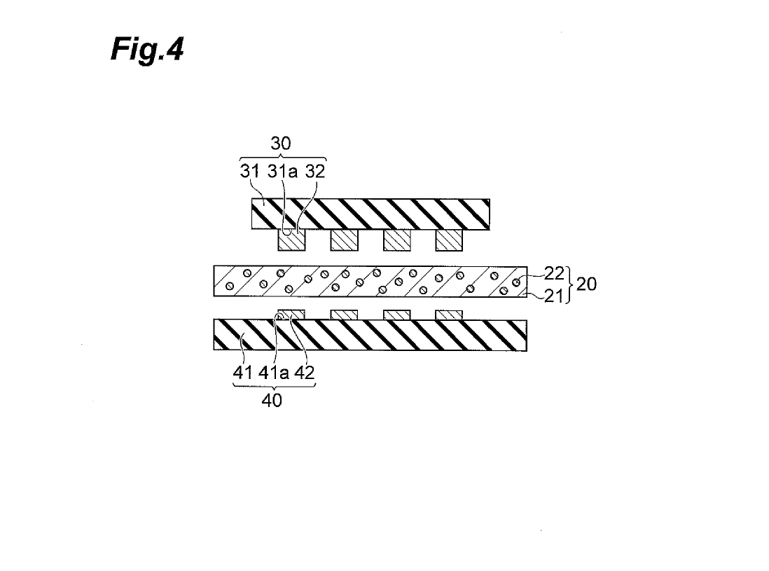

FIG. 3 is a schematic cross-sectional view of an embodiment of a circuit member connection structure employing an adhesive composition of the invention that contains (d) conductive particles. FIG. 4 is a schematic cross-sectional view of a first circuit member, a second circuit member and an adhesive composition (containing conductive particles), before forming the circuit member connection structure shown in FIG. 3.

The circuit member connection structure 200 shown in FIG. 3 comprises a first circuit member 30 having a first connecting terminal 32 on the main surface 31a of a first circuit board 31, a second circuit member 40 having a second connecting terminal 42 on the main surface 41a of a second circuit board 41, and a connecting member 20C that connects the main surface 31a of the first circuit board 31 and the main surface 41a of the second circuit board 41, in such a manner that the first connecting terminal 32 and second connecting terminal 42 are facing each other. The connecting member 20C is the cured adhesive composition 20 having conductive particles 22 dispersed in the components 21 other than the conductive particles of the adhesive composition (that is, the dispersion of the conductive particles 22 in the cured product 21C of the components of the adhesive composition other than the conductive particles), and contact of the conductive particles 22 with both connecting terminals between the mutually facing first connecting terminal 32 and second connecting terminal 42 establishes electrical connection of the connecting terminals through the conductive particles 22.

The circuit member connection structure 200 shown in FIG. 3 may be produced, for example, by preparing the first circuit member 30, the second circuit member 40 and the adhesive composition 20 that has been formed into a film, as shown in FIG. 4, and using the same method as that used to obtain the circuit member connection structure 100.

Either or both the first circuit member 30 and second circuit member 40 are made of a base material containing a thermoplastic resin with a glass transition temperature of no higher than 200° C., and preferably made of a base material containing at least one thermoplastic resin with a glass transition temperature of no higher than 200° C., selected from the group consisting of polyethylene terephthalate, polycarbonate and polyethylene naphthalate. That is, either or both the first circuit board 31 and second circuit board 41 preferably contain at least one compound selected from the group consisting of polyethylene terephthalate, polycarbonate and polyethylene naphthalate. If either or both of the first circuit member 30 and second circuit member 40 are a circuit member made of a base material containing at least one selected from the group consisting of polyethylene terephthalate, polycarbonate and polyethylene naphthalate, the wettability with the adhesive composition will be improved and the bonding strength will be further increased. Such a circuit member connection structure can therefore exhibit more excellent connection reliability.

Either or both the first circuit member 30 and second circuit member 40 may also be made of a base material that does not contain a thermoplastic resin with a glass transition temperature of no higher than 200° C. such as polyethylene terephthalate, polycarbonate or polyethylene naphthalate. Base materials that form such circuit members may be base materials made of inorganic materials such as semiconductors, glass, ceramic or the like, base materials made of organic materials such as polyimide or polycarbonate, or base materials comprising a combination of inorganic and organic materials such as glass/epoxy.

Also, either or both the first connecting terminal 32 and second connecting terminal 42 are made of at least one compound selected from the group consisting of and ITO and IZO. ITO and IZO are easily etched and have excellent pattern formability, and are therefore suitable for connecting terminals. By using an adhesive composition of the invention it is possible to sufficiently inhibit corrosion of connecting terminals made of ITO and/or IZO.

Incidentally, either the first connecting terminal 32 or second connecting terminal 42 may also be made of a material other than ITO and IZO. Such connecting terminals may be connecting terminals made of metals such as copper, silver, aluminum, gold, palladium or nickel, or their alloys.

### EXAMPLES

The present invention will now be explained in greater detail based on examples and comparative examples, with the understanding that the invention is in no way limited to the examples.

<Thermoplastic Resin>

### (Preparation of Phenoxy Resin)

There was dissolved 40 parts by mass of a phenoxy resin (trade name: YP-50, product of Tohto Kasei Co., Ltd.) in 60 parts by mass of methyl ethyl ketone to produce a solution with a solid content of 40 mass %.

(Preparation of Polyester-Urethane Resin)

A polyester-urethane resin (trade name: UR-1400, product of Toyobo, Ltd.) was used as a solution in a 1:1 mixture of methyl ethyl ketone and toluene, with a resin content of 30 mass %.

(Synthesis of Urethane Resin)

After dissolving 450 parts by mass of polybutylene adipate diol with a weight-average molecular weight 2000 (product of Aldrich Co.), 450 parts by mass of polyoxytetramethylene glycol with an average molecular weight of 2000 (product of Aldrich Co.) and 100 parts by mass of 1,4-butylene glycol (product of Aldrich Co.) in 4000 parts by mass of methyl ethyl ketone (product of Wako Pure Chemical Industries, Ltd.), 390 parts by mass of diphenylmethane diisocyanate (product of Aldrich Co.) was added and reaction was conducted at 70° C. for 60 minutes to obtain a urethane resin. The weight-average molecular weight of the obtained urethane resin was measured by GPC to be 100,000.

<Radical Polymerizing Compound>

### (Synthesis of Urethane Acrylate (UA))

In a reactor equipped with a stirrer, a thermometer, a reflux condenser with a calcium chloride drying tube, and a nitrogen gas inlet tube, there were loaded 238 parts by mass (2.05 mol) of 2-hydroxyethyl acrylate (product of Aldrich Co.), 0.53 part by mass of hydroquinone monomethyl ether (product of Aldrich Co.), 4000 parts by mass (2.00 mol) of poly(3-methyl-1,5-pentanediol adipate) dial with a number-average molecular weight of 2000 (product of Aldrich Co.) and 5.53 parts by mass of dibutyltin dilaurate (product of Aldrich Co.). After sufficiently introducing nitrogen gas, the mixture was heated to 70° C. to 75° C., and 666 parts by mass (3.00 mol) of isophorone diisocyanate (product of Aldrich Co.) was uniformly added dropwise over a period of 3 hours for reaction. Upon completion of the dropwise addition, reaction was continued for approximately 15 hours, and the reaction was terminated upon confirming disappearance of the isocyanate by IR, to obtain urethane acrylate (UA). The number-average molecular weight of the obtained urethane acrylate (UA) was 3700.

<Phosphate Group-Containing Compound>

There were prepared bis[2-((meta)acryloyloxy)ethyl]phosphate (product of Aldrich Co.), phosphoric acrylate (trade name: PM2, product of Nippon Kayaku Co., Ltd.) and dibutyl phosphate (product of Aldrich Co.). The bis[2-((meta)acryloyloxy)ethyl]phosphate and phosphoric acrylate (PM2) function as radical polymerizing compounds.

<Radical Polymerization Initiator>

As a radical polymerization initiator there was prepared t-hexylperoxy-2-ethyl hexanoate (trade name: PERHEXYL O, product of NOF Corp.).

<Conductive Particles>

### (Formation of Conductive Particles)

A nickel layer with a thickness of 0.2 μm was formed on the surface of particles having polystyrene cores, and then a gold layer was formed on the outside of the nickel layer to a thickness of 0.02 μm to produce conductive particles with a mean particle size of 10 μm and a specific gravity of 2.5.

### Examples 1 to 8 and Comparative Examples 1 to 5

The components were mixed in the solid mass ratios shown in Table 3, and the conductive particles were added and dispersed at 1.5 vol % based on the total solid volume of the adhesive compositions, to obtain adhesive compositions. Each obtained adhesive composition was coated onto an 80 μm-thick fluorine resin film using a coating apparatus and dried with hot air at 70° C. for 10 minutes to obtain a film-like adhesive composition with an adhesive layer thickness of 20 μm.

The free phosphate concentration of each cured adhesive composition was measured in the following manner. First, the adhesive composition was cured by heat drying at 180° C. for 1 hour. Next, the sample (cured adhesive composition) and ultrapure water were added to an autoclave vessel to a sample content of 1 mass %, and the mixture was heated in a hot air dryer at 121° C., 0.2 MPa for 15 hours to obtain an extract. The obtained extract was measured by ion chromatography, and the free phosphate concentration was calculated using a calibration curve for Anion Mixed Standard Solution IV (product of Kanto Kagaku Co., Ltd.). The measuring conditions for the ion chromatography were as shown in Table 2 above. The free phosphate concentrations of the cured adhesive compositions are shown in Table 3.

TABLE 3

| | | Example | | | | | | | | Comp. Ex. | | | | |
|---|---|---|---|---|---|---|---|---|---|---|---|---|---|---|
| Additive | | 1 | 2 | 3 | 4 | 5 | 6 | 7 | 8 | 1 | 2 | 3 | 4 | 5 |
| Thermoplastic resin | YP-50 | 50 | 50 | — | — | 50 | — | 50 | — | 50 | — | 50 | — | — |
| | UR-1400 | — | — | 50 | 50 | — | 50 | — | 50 | — | 50 | — | 50 | 50 |
| Urethane resin | | 5 | 5 | 5 | 5 | 5 | 5 | 5 | 5 | 5 | 5 | 5 | 5 | 5 |
| Radical polymerizing | UA | 45 | 45 | 45 | 45 | 45 | 45 | 45 | 45 | 45 | 45 | 45 | 45 | 45 |
| compound | | | | | | | | | | | | | | |
| Phosphate group- | Bis[2- | 1 | 3 | 1 | 3 | — | — | — | — | — | — | — | — | — |
| containing compound | ((meth)acryloyloxy) | | | | | | | | | | | | | |
| | ethyl] phosphate | | | | | | | | | | | | | |
| | PM2 | — | — | — | — | 1 | 1 | — | — | 3 | 3 | — | — | — |
| | Dibutyl phosphate | — | — | — | — | — | — | 0.5 | 0.5 | — | — | 1 | 1 | — |
| Radical polymerization | Perhexyl O | 3 | 3 | 3 | 3 | 3 | 3 | 3 | 3 | 3 | 3 | 3 | 3 | 3 |
| initiator | | | | | | | | | | | | | | |

| | | | | | | | | | | | | | |
|---|---|---|---|---|---|---|---|---|---|---|---|---|---|
| Free phosphate concentration (ppm by mass) | 30 | 70 | 34 | 65 | 54 | 85 | 59 | 76 | 120 | 129 | 113 | 125 | 0 |

[Measurement of Connection Resistance and Bonding Strength]

The film-like adhesive compositions of Examples 1 to 8 and Comparative Examples 1 to 5 were each situated between a flexible printed circuit (FPC) having 250 copper circuits with a line width of 50 μm, a pitch of 100 μm and a thickness of 18 μm on a polyimide film (Tg: 350° C.), and a PET board having a thin layer of IZO formed to a thickness of 0.2 μm on a PET film (Tg: 120° C.) (thickness: 0.1 mm, surface resistance: 30 Ω/sq.). This was hot pressed at 150° C., 2 MPa for 10 seconds using a thermocompression bonding apparatus (heating system: constant heating, product of Toray Engineering Co., Ltd.), for connection across a width of 2 mm to produce a connection structure. The resistance value between the adjacent circuits of the connection structure was measured using a multimeter immediately after bonding and after holding for 240 hours in a high-temperature, high-humidity vessel at 85° C., 85% RH (after testing). The resistance value was expressed as the average of 37 resistance points between the adjacent circuits.

The bonding strength of the connection structure was measured by the 90 degree peel method of JIS-Z0237 and evaluated. The bonding strength measuring apparatus used was a TENSILON UTM-4 by Toyo Baldwin Co., Ltd. (peel rate: 50 ram/min, measuring temperature: 25° C.). The measurement results for the connection resistance and bonding strength of the film-like adhesive compositions, conducted as described above, are shown in Table 4 below.

[Corrosion Evaluation]

The film-like adhesive compositions of Examples 1 to 8 and Comparative Examples 1 to 5 were each situated between a flexible printed circuit (FPC) having 250 copper circuits with a line width of 100 μm, a pitch of 200 μm and a thickness of 18 μm on a polyimide film (Tg: 350° C.), and a PET board having an ITO circuit formed on a PET film (Tg: 120° C.) to a line width of 100 μm, a pitch of 200 μm and a thickness of 0.2 μm, or a PET board having an IZO circuit formed on a PET film (Tg:120° C.) to a line width of 100 μm, a pitch of 200 μm and a thickness of 0.2 μm. This was subjected to thermocompression bonding by the same method and under the same conditions as for measurement of the connection resistance and bonding strength, to produce a connection structure. The connection structure was held in a high-temperature, high-humidity vessel at 85° C., 85% RH for 240 hours, and then the presence or absence of corrosion of the ITO circuit or IZO circuit was observed using an optical microscope. Corrosion was judged to be present if at least a portion of the ITO circuit or IZO circuit had been lost by elution, and corrosion was judged to be absent if no elution of the ITO circuit or IZO circuit was found. The evaluation results for circuit corrosion conducted as described above are shown in Table 4 below.

TABLE 4

| | Connection | | Bonding strength (N/m) | | Circuit | |
|---|---|---|---|---|---|---|
| | resistance (Ω) | | IZO | | corrosion | |
| | Immediately | After | Immediately | After | ITO | IZO |
| | after bonding | 240 h | after bonding | 240 h | After 240 h | |
| Example 1 | 1.2 | 1.6 | 650 | 620 | − | − |
| Example 2 | 1.4 | 1.8 | 670 | 650 | − | − |
| Example 3 | 1.5 | 1.9 | 640 | 630 | − | − |
| Example 4 | 1.2 | 1.6 | 680 | 600 | − | − |
| Example 5 | 1.5 | 1.9 | 600 | 630 | − | − |
| Example 6 | 1.2 | 1.6 | 610 | 600 | − | − |
| Example 7 | 1.6 | 1.9 | 570 | 550 | − | − |
| Example 8 | 1.4 | 1.7 | 600 | 570 | − | − |
| Comp. Ex. 1 | 1.3 | 1.6 | 530 | 520 | + | + |
| Comp. Ex. 2 | 1.5 | 1.9 | 500 | 490 | + | + |
| Comp. Ex. 3 | 1.6 | 1.7 | 550 | 510 | + | + |
| Comp. Ex. 4 | 1.8 | 2.0 | 690 | 620 | + | + |
| Comp. Ex. 5 | 1.2 | 1.4 | 380 | 200 | − | − |

Since the adhesive compositions composing the connecting members obtained in Examples 1 to 8 had free phosphate concentrations of no greater than 100 ppm by mass in the cured products, with a heating temperature of 150° C., no circuit corrosion was observed either after bonding or even after holding for 240 hours in a high-temperature, high-humidity vessel at 85° C., 85% RH (after testing), and satisfactory connection resistance and bonding strength were clearly exhibited.

In contrast, Comparative Examples 1 to 4 had free phosphate concentrations exceeding 100 ppm by mass in the cured adhesive compositions composing the connecting members, and therefore satisfactory bonding strength was obtained immediately after bonding and after holding for 240 hours in a high-temperature, high-humidity vessel, but circuit corrosion clearly occurred after holding for 240 hours in the high-temperature, high-humidity vessel (after testing). Also, Comparative Example 5, which contained no phosphate group-containing compound, exhibited no corrosion of the circuits, but due to reduced adhesiveness at the interface between the circuit made of copper and the circuit made of IZO, the adhesive force was clearly low immediately after bonding and after holding for 240 hours in the high-temperature, high-humidity vessel.

### Reference Examples 1 to 8

The film-like adhesive compositions of Examples 1 to 6 and Comparative Examples 1 and 2 were each situated between a flexible printed circuit (FPC) having 500 copper circuits with a line width of 25 μm, a pitch of 50 μm and a thickness of 18 μm on a polyimide film (Tg: 350° C.), and glass having a thin layer of indium oxide (ITO) formed to a thickness of 0.20 μm (thickness: 1.1 mm, surface resistance: 20 Ω/sq.). This was subjected to thermocompression bonding by the same method and under the same conditions as for measurement of the connection resistance and bonding strength, to produce a connection structure. The connection resistance, bonding strength and presence or absence of circuit corrosion of the connection structure were measured by the same methods described above. The results are shown in Table 5 below.

TABLE 5

| | | Connection | | Bonding | | Circuit |
|---|---|---|---|---|---|---|
| | | resistance (Ω) | | strength (N/m) | | corrosion |
| | Adhesive | Immediately | After | Immediately | After | After |
| | composition | after bonding | 240 h | after bonding | 240 h | 240 h |
| Ref. | Example 1 | 1.4 | 1.8 | 750 | 680 | − |
| Ex. 1 | | | | | | |
| Ref. | Example 2 | 1.2 | 1.7 | 800 | 700 | − |
| Ex. 2 | | | | | | |
| Ref | Example 3 | 1.3 | 1.7 | 750 | 690 | − |
| Ex. 3 | | | | | | |
| Ref. | Example 4 | 1.2 | 1.6 | 790 | 680 | − |
| Ex. 4 | | | | | | |
| Ref | Example 5 | 1.5 | 1.7 | 780 | 650 | − |
| Ex. 5 | | | | | | |
| Ref. | Example 6 | 1.4 | 1.6 | 720 | 680 | − |
| Ex. 6 | | | | | | |
| Ref. | Comp. | 1.5 | 1.6 | 690 | 620 | − |
| Ex. 7 | Ex. 1 | | | | | |
| Ref | Comp. | 1.4 | 1.9 | 700 | 630 | − |
| Ex. 8 | Ex. 2 | | | | | |

The adhesive compositions composing the connecting members obtained in Reference Examples 1 to 8, regardless of the free phosphate concentration in the cured product, had no observable circuit corrosion either after bonding or even after holding for 240 hours in a high-temperature, high-humidity vessel at 85° C., 85% RH (after testing), and satisfactory connection resistance and bonding strength were clearly exhibited. This confirmed that a circuit member made of a base material containing a thermoplastic resin with a glass transition temperature of no higher than 200° C. differs in terms of the quality of connection reliability, from FPC boards or transparent electrode-formed glass boards that are conventionally used as circuit members.

These results confirmed that, for formation of connection between a first circuit member having a first connecting terminal on the main surface and a second circuit member having a second connecting terminal on the main surface using an adhesive composition, when the first circuit member and/or second circuit member are made of a base material containing a thermoplastic resin with a glass transition temperature of no higher than 200° C., the first connecting terminal and/or second connecting terminal are made of ITO and/or IZO, and an adhesive composition of the invention is used which contains a phosphate group-containing compound, and the free phosphate concentration being no greater than 100 ppm by mass in the cured adhesive composition, it is possible to inhibit elution of the connecting terminals on the connecting members having connecting terminals made of amorphous-structured ITO or IZO, and to obtain excellent bonding strength, while maintaining stable performance (bonding strength and connection resistance) even after prolonged reliability testing (high-temperature, high-humidity testing).

### INDUSTRIAL APPLICABILITY

As explained above, according to the invention it is possible to provide an adhesive composition that inhibits elution of connecting terminals on connecting members that have connecting terminals made of ITO or IZO, and that can exhibit excellent bonding strength and can maintain stable performance (bonding strength and connection resistance) even after prolonged reliability testing (high-temperature, high-humidity testing), as well as the use thereof, a circuit member connection structure employing the adhesive composition, and a method for producing the same.

### EXPLANATION OF SYMBOLS

10, 20: Adhesive compositions, 10C, 20C: connecting members, 21: adhesive composition containing no conductive particles, 22: conductive particles, 21C: cured adhesive composition containing no conductive particles, 30: first circuit member, 31: first circuit board, 31a: main surface, 32: first connecting terminal, 40: second circuit member, 41: second circuit board, 41a: main surface, 42: second connecting terminal, 100, 200: circuit member connection structures.

1. An adhesive composition for connection between a first circuit member having a first connecting terminal on the main surface and a second circuit member having a second connecting terminal on the main surface, wherein:
the first circuit member and/or second circuit member are made of a base material containing a thermoplastic resin with a glass transition temperature of no higher than 200° C.,
the first connecting terminal and/or second connecting terminal are made of ITO and/or IZO, and
the adhesive composition includes a phosphate group-containing compound,
the free phosphate concentration of the cured adhesive composition being no greater than 100 ppm by mass.

2. The adhesive composition according to claim 1, which contains (a) a thermoplastic resin, (b) a radical polymerizing compound and (c) a radical polymerization initiator, and the (b) radical polymerizing compound includes the phosphate group-containing compound.

3. The adhesive composition according to claim 2, wherein the (b) radical polymerizing compound contains one or more of both a vinyl compound with a phosphate group, as the phosphate group-containing compound, and a radical polymerizing compound other than the vinyl compound with a phosphate group.

4. The adhesive composition according to claim 1, which further comprises (d) conductive particles.

5. The adhesive composition according to claim 1, wherein either or both the first circuit member and second circuit member are made of a base material containing a thermoplastic resin with a glass transition temperature of no higher than 200° C., and have a connecting terminal made of ITO and/or IZO on the main surface.

6. The adhesive composition according to claim 1, wherein the thermoplastic resin with a glass transition temperature of no higher than 200° C. is at least one selected from the group consisting of polyethylene terephthalate, polycarbonate and polyethylene naphthalate.

7. A circuit member connection structure comprising a first circuit member having a first connecting terminal on the main surface, a second circuit member having a second connecting terminal on the main surface, and a connecting member, wherein:
the first circuit member and the second circuit member are disposed in such a manner that the first connecting terminal and the second connecting terminal face each other via the connecting member made of an adhesive composition according to claim 1, the first connecting terminal and second connecting terminal being electrically connected, and
the first circuit member and/or second circuit member are made of a base material including a thermoplastic resin with a glass transition temperature of no higher than 200° C., and
the first connecting terminal and/or second connecting terminal are made of ITO and/or IZO.

8. The circuit member connection structure according to claim 7, wherein the thermoplastic resin with a glass transition temperature of no higher than 200° C. is at least one selected from the group consisting of polyethylene terephthalate, polycarbonate and polyethylene naphthalate.

9. A method for producing a circuit member connection structure which comprises a step of:
disposing a first circuit member having a first connecting terminal on the main surface and
a second circuit member having a second connecting terminal on the main surface
in such a manner that the first connecting terminal and the second connecting terminal face each other, and
situating an adhesive composition according to claim 1 between the first circuit member and the second circuit member and hot pressing them to form electrical connection between the first connecting terminal and second connecting terminal,
the first circuit member and/or second circuit member being made of a base material containing a thermoplastic resin with a glass transition temperature of no higher than 200° C., and
the first connecting terminal and/or second connecting terminal being made of ITO and/or IZO.

10. The method for producing a circuit member connection structure according to claim 9, wherein the thermoplastic resin with a glass transition temperature of no higher than 200° C. is at least one selected from the group consisting of polyethylene terephthalate, polycarbonate and polyethylene naphthalate.

11. A use of an adhesive composition according to claim 1,
for connection between a first circuit member having a first connecting terminal on the main surface and a second circuit member having a second connecting terminal on the main surface, wherein:
the first circuit member and/or second circuit member are made of a base material including a thermoplastic resin with a glass transition temperature of no higher than 200° C., and
the first connecting terminal and/or second connecting terminal are made of ITO and/or IZO.

12. The use according to claim 11, wherein the thermoplastic resin with a glass transition temperature of no higher than 200° C. is at least one selected from the group consisting of polyethylene terephthalate, polycarbonate and polyethylene naphthalate.
